(19) United States
(12) Patent Application Publication
(10) Pub. No.: US 2005/0028055 A1
(43) Pub. Date: Feb. 3, 2005

(54) System and method for reducing waveform distortion in transferring signals

(76) Inventor: Feng Zhang, Shenzhen (CN)

Correspondence Address: WEI TE CHUNG;FOXCONN INTERNATIONAL, INC., 1650 MEMOREX DRIVE, SANTA CLARA, CA, 95050, US

(21) Appl. No.: 10/910,070

(22) Filed: Aug. 2, 2004

(30) Foreign Application Priority Data
Aug. 1, 2003 (TW) 92121180

(51) Int. Cl. G01R 31/28

(52) U.S. Cl. 714/712

(57) ABSTRACT

A system and a method for reducing waveform distortion in transferring signals includes a clock signal and at least a receiver. The interconnect distance between the clock and the receiver is the distance traveled by the clock signal in a quarter of a period of the clock signal. The system and method are also applicable to non-clock signals.

### BACKGROUND OF THE INVENTION

1. Field of the Invention

The present invention relates generally to a system and a method for transferring electronic signals, and more particularly to a system and a method for reducing waveform distortion in transferring signals.

2. Prior Art

These days, the ever increasing clock frequency for operating electronic components has brought about much higher demands on the interconnections between each of the electronic components.

It is well known in the industry of integrated circuit (IC) fabrication that various kinds of unavoidable parasitic effects are present on the pins of electronic components. These parasitic effects include resistance parasitic effect, capacitance parasitic effect and inductance parasitic effect. If no appropriate action is taken, the presence of such parasitic effects generates a spike when transferring high-speed signals through each pin of the component, thus distorting the waveform of the signals.

FIG. 7 illustrates a topological diagram of a typical connection between a signal source and a receiving end of an electronic component. As shown in the figure, the presence of a resistor 110 is essential for normal operation of this schematic connection. As shown, the frequency of the clock signal source is 33.3 MHz, while the period thereof is 30 ns. Two interconnection lengths of a transmission line 200 between a driving unit 100 and a receiving unit 300 are defined. The first interconnection length is the distance traveled by the signal in a time delay of 3 ns (one-tenth of a clock period, as shown by a first location 150), and the second interconnection length is the distance traveled by the signal a time delay of 8 ns (1/3.75 of a clock period, as shown by a second location 180). Referring also to FIG. 8, in the case of the first interconnection length, a resultant output signal measured at the receiving unit 300 in accordance with software simulation is represented by curve 120. In the case of the second interconnection length, the resultant output signal is represented by curve 140. In both cases, the clock signal is partially distorted in the transmission process due to the existence of parasitic effects on the pin of the driving unit 100. That is, a spike is generated at the pin of the driving unit 100, and the spike distorts the waveform when transferring the high frequency clock signal through the driving unit 100. The waveform distortion may induce many negative effects on the electronic component and may undermine the normal operation of the electronic component, especially at high frequencies. The question of how to improve the problem of waveform distortion is of major concern in the art.

### SUMMARY OF THE INVENTION

A primary objective of the present invention is to provide a system and a method for reducing waveform distortion in transferring signals.

In order to achieve the above objective, a system of the present invention for reducing waveform distortion in transferring signals comprises a clock signal source, and at least a receiving end electronic component. The interconnection length between the clock signal source and the receiving end electronic component is the distance traveled by the signal in a quarter of a period of the clock signal source.

The present invention also discloses a method for reducing waveform distortion in transferring signals, the method comprising the steps of: providing a signal source with a working frequency; providing a transmission speed for a signal in a system medium; and controlling an interconnection length between the signal source and a receiving end electronic component as being a distance traveled by the signal in a quarter of a period of the signal.

The system and the method are also equally applicable to non-clock signals.

The technical features of the present invention provide the following advantages: easy implementation, no need for additional elements, and cost effectiveness. The method substantially reduces parasitic effects on the pins of electronic components and the effect of ground bounce, so as to markedly improve the quality of signal transmission and maintain signal integrity.

### BRIEF DESCRIPTION OF THE DRAWINGS

FIG. 1 is a circuit diagram of a system for reducing waveform distortion in transferring signals in accordance with the present invention, the system comprising a driving unit (clock signal source) and a receiving unit (electronic component).

FIG. 2 is a waveform diagram obtained at the receiving unit of the system of FIG. 1, when a signal input by the driving unit has a frequency of 100 MHz, and a transmission delay time between the clock signal source and the electronic component is 0.5 ns.

FIG. 3 is a waveform diagram obtained under conditions similar to those for FIG. 2, but with the transmission delay time being 2.5 ns.

FIG. 4 is a waveform diagram obtained under conditions similar to those for FIG. 2, but with the transmission delay time being 3.0 ns.

FIG. 5 is a waveform diagram obtained under conditions similar to those for FIG. 2, but with the input signal having a frequency of 300 MHz, and the transmission delay time being 0.8 ns.

FIG. 6 is a waveform diagram obtained under conditions similar to those for FIG. 5, but with the transmission delay time being 0.833 ns.

FIG. 7 is a topological structure diagram of a conventional connection between a signal source and a receiving end of an electronic component.

FIG. 8 is a waveform diagram obtained for the electronic component represented in FIG. 7, showing waveforms corresponding to transmission delay times of 3 ns and 8 ns respectively.

### DESCRIPTION OF THE PREFERRED EMBODIMENTS

It is well known that, in practice, parasitic effects such as parasitic inductance and parasitic resistance are present in each pin of an IC chip. These parasitic effects generate a spike distortion when transferring a high-speed signal with a very high frequency through the pin. The system and the method of the present invention substantially reduce or eliminate spike distortion due to parasitic effects.

The system for reducing waveform distortion in transferring signals comprises a clock signal source and a receiving end electronic component. An interconnection length between the clock signal source and the receiving end electronic component is a distance traveled by a signal in a quarter of a period of the clock signal source. The system is also applicable to non-clock signal sources.

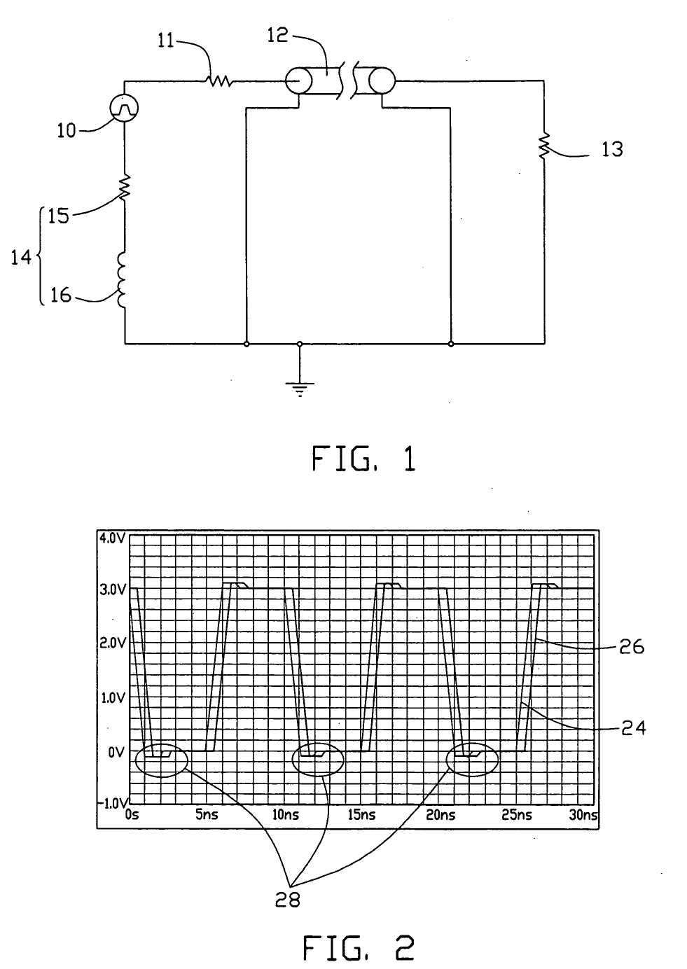

FIG. 1 illustrates the principles of the system for reducing waveform distortion in transferring signals. As shown, the driving unit 10 provides a clock signal with a frequency of 100 MHz and a period of 10 ns; a receiving unit 13 is the receiving end electronic component; a delay transmission unit 12 simulates a transmission delay distance of a transmission line; and a parasitic effect unit 14 comprises a resistor 15 and a inducer 16 simulating the parasitic effects on a pin of the driving unit 10. One end of the driving unit 10 is connected with one end of the delay transmission unit 12 via the resistor 11. The other end of the driving unit 10 is connected with the parasitic effect unit 14 and with ground. The other end of the delay transmission unit 12 is connected with the receiving unit 13. The parameters of the delay transmission unit 12 may be tuned in order to obtain the desired delay distance of the transmission line. An output waveform simulated by software may be used at the receiving unit 13.

FIG. 2 and FIG. 4 show waveform diagrams at the receiving unit 13 when the transmission delay time between the clock signal source and the electronic component is 0.5 ns and 3 ns respectively. Curves 24 and 44 are the input curves of the driving unit 10, while curves 26 and 46 are the output curves of the receiving unit 13. As shown, the waveform is distorted at third locations 28 (FIG. 2) and fourth locations 48 (FIG. 4). It is known in the art that the spike distortions manifest at the transmission delay times of 0.5 ns and 3 ns are primarily due to the parasitic effects on the pin of the driving unit 10.

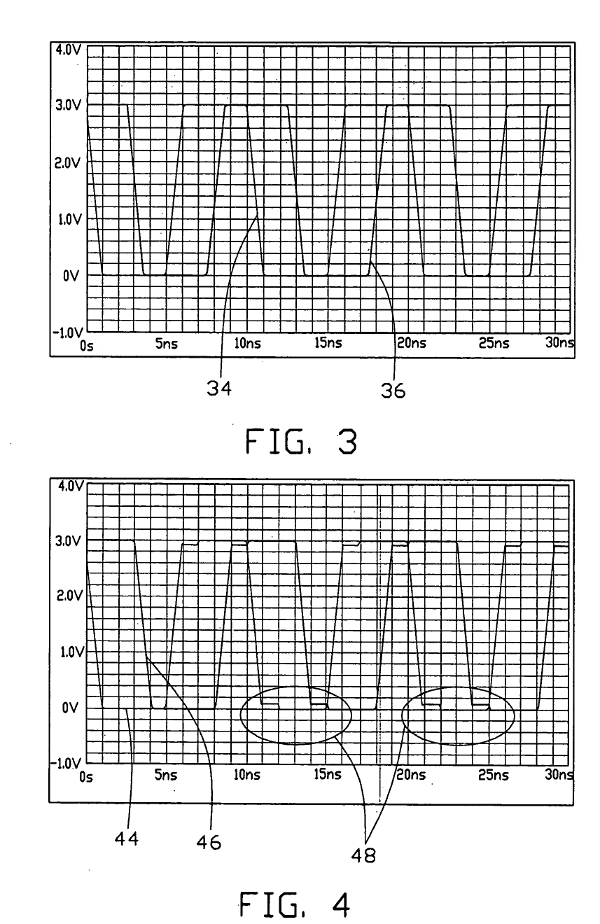

FIG. 3 shows waveform diagrams at the receiving unit 13 with a transmission delay time of 2.5 ns. That is, the interconnection length between the driving unit 10 and the receiving unit 13 is controlled to be the distance traveled by the clock signal in a quarter of a period. Curve 34 is the input curve of the driving unit 10, while curve 36 is the output curve of the receiving unit 13. As shown, the input and output waveforms are very smooth. The clock signal retains its integrity without any spike distortion during the transmission process.

The reason for this is, at the beginning of transmitting the clock signal, a positive waveform is emitted from the driving unit 10 to the receiving unit 13, and is reflected back by the receiving unit 13. Since the length of the delay transmission unit 12 is a quarter of a period, the positive waveform reflected by the receiving unit 13 returns to the driving unit 10 after half a clock period, and a positive spike is generated due to the parasitic effect on the pin of the driving unit 10. Simultaneously, the driving unit 10 emits a negative waveform signal to the receiving unit 13, and a negative spike is generated at the pin. The positive spike generated from the reflected positive waveform and the negative spike generated from the negative waveform cancel each other out, thus making the waveform smooth. The clock signal thus retains its integrity without any spike distortion during the transmission process.

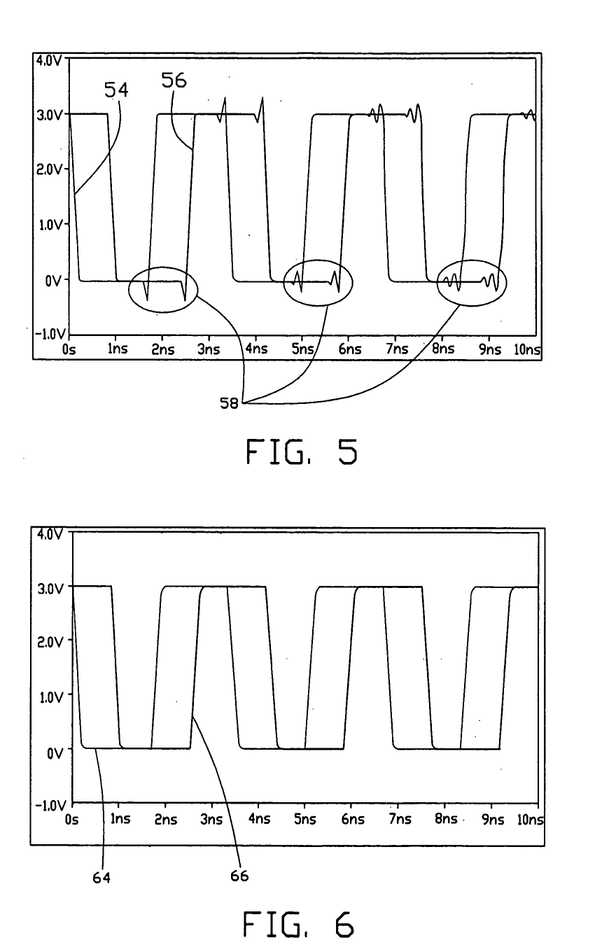

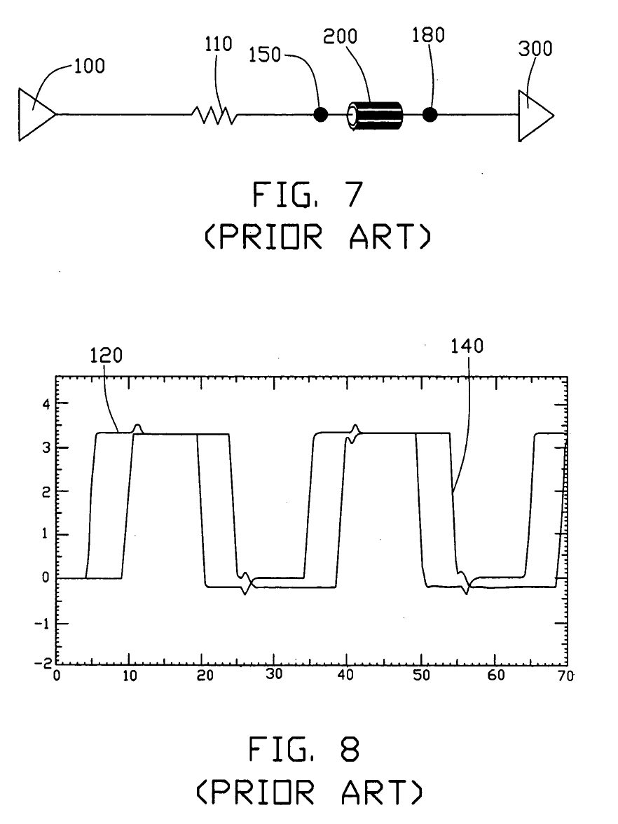

FIG. 5 and FIG. 6 illustrate waveform diagrams at a clock frequency of 300 MHz. FIG. 5 is the waveform diagram when the transmission delay time is 0.8 ns. FIG. 6 is the waveform diagram when the transmission delay time is 0.8333 ns; i.e., when the distance between the clock signal source and the electronic component is the distance traveled by the signal in a quarter of a period. Curves 54 and 64 are the input curves of the driving unit 10, while curves 56 and 66 are the output curves of the receiving unit 13. As shown, the waveform is distorted at fifth locations 58 (FIG. 5) when the distance between the clock signal source and the electronic component is the distance traveled by the clock signal for a transmission delay time of 0.8 ns. However, the waveform remains undistorted (FIG. 6) when the distance between the clock signal source and the electronic component is the distance traveled by the clock signal in a quarter of a period. That is, the clock signal retains its integrity.

To summarize the method of the present invention, it comprises the steps of: providing a signal source with a working frequency; providing a transmission speed for a signal in a system medium; and controlling an interconnection length between the signal source and a receiving end electronic component as being a distance traveled by the signal in a quarter of a period of the signal.

The system and the method of the present invention for reducing waveform distortion in transferring signals may also be applied to non-clock signals. The system and the method employ the above-described cancellation effect when the positive and negative waveforms meet at the driving unit 10 after half a period. For non-clock signals, it is 50% likely that the driving unit 10 would revert its logic state after half a period, in which case the aforementioned conditions would be satisfied. Therefore, 50% of the waveforms for non-clock signals may be improved by the present invention.

The system and the method for reducing waveform distortion in transferring clock signals may be applied to the interconnection between the clock source of a motherboard and associated electronic devices. The interconnection length between the clock signal and each electronic component may be derived according to the method of the present invention for interconnecting the clock signal and the electronic component, and by incorporating the following formula (1):
L=v*t=vT/4=v/4f (1)

In formula (1), L is the length of the transmission line, T is the period of the clock signal, v is the transmission speed of the clock signal on the motherboard, t is the transmission time of the clock signal on the motherboard, and f is the frequency of the clock signal.

At present, the highest working frequency of clock signal sources on motherboards is 200 MHz, and the transmission speed of clock signals on motherboards is approximately 6 inches/ns. According to the method of the present invention for interconnecting the clock signal and the electronic component, and by incorporating the above formula (1), the length L of the transmission line between the clock signal source and the electronic component on the motherboard should be 7.5 inches. However, in practice, the length of the transmission line used in a typical present-day circuit board is approximately 5 inches. With the length L being 5 inches, the signals would inevitably be delayed, thus inducing a signal distortion. However, if the working frequency of the clock signal on the motherboard were about 300 MHz, the length L would be exactly 5 inches as calculated in accordance with the above formula (1). Therefore, at a time when the working frequency of the motherboard is able to be 300 MHz, employing a transmission line 5 inches in length should provide the needed delay for the clock signal, thereby reducing or eliminating signal distortion.

Similarly, the system and the method of the present invention for reducing waveform distortion in transferring signals may also be employed in the design of integrated circuits (ICs), cables, and interconnections between electronic devices in printed circuit boards (PCBs).

It is noted that the above descriptions disclose only the preferred embodiments of the present invention. Any modification or alteration to the preferred embodiments by one skilled in the art according to the spirit of the present invention are considered within the scope of the following claims and/or equivalents thereof.

1. A system for reducing waveform distortion in transferring signals, comprising:
a signal source; and
at least a receiving end electronic component;
wherein an interconnection length between the signal source and said receiving end electronic component is a distance traveled by a signal in a quarter of a period of the signal.

2. The system as recited in claim 1, wherein the signal source is a clock signal source.

3. The system as recited in claim 1, further comprising a printed circuit board incorporating the signal source and said receiving end electronic component.

4. The system as recited in claim 1, further comprising an integrated circuit incorporating the signal source and said receiving end electronic component.

5. The system as recited in claim 3, wherein the printed circuit board is a motherboard.

6. A method for reducing waveform distortion in transferring signals, comprising the steps of:
providing a signal source with a working frequency;
providing a transmission speed for a signal in a system medium; and
controlling an interconnection length between the signal source and a receiving end electronic component to be a distance traveled by the signal in a quarter of a period of the signal.

7. The method as recited in claim 6, wherein the signal source is a clock signal source.

8. A system for reducing waveform distortion in transferring signals, comprising:
a signal source; and
at least a receiving end electronic component;
wherein an interconnection length between the signal source and said receiving end electronic component is a distance traveled by a signal in a quarter of a period of the signal or a function of said quarter which is capable of reducing waveform distortion in transferring signals.
